(19) United States
(12) Patent Application Publication
(10) Pub. No.: US 2005/0280087 A1
(43) Pub. Date: Dec. 22, 2005

(54) Laterally diffused MOS transistor having source capacitor and gate shield

(75) Inventors: Jeff Babcock, Sunnyvale, CA (US); Johan Agus Darmawan, Cupertino, CA (US); John Mason, Sunnyvale, CA (US)

Correspondence Address: BEYER WEAVER & THOMAS LLP, P.O. BOX 70250, OAKLAND, CA, 94612-0250, US

(73) Assignee: CREE MICROWAVE, INC., SUNNYVALE, CA (US)

(21) Appl. No.: 10/870,795

(22) Filed: Jun. 16, 2004

(51) Int. Cl. H01L 27/108

(52) U.S. Cl. 257/343

(57) ABSTRACT

An LDMOS transistor includes a source capacitor structure and a gate-drain shield which can be interconnected whereby the source capacitor can be grounded to provide an RF ground for the shield and whereby the RF shield can have a positive DC voltage bias to enhance laterally diffused drain conductance without increasing doping therein.

### CROSS-REFERENCE TO RELATED APPLICATIONS

This application is related to co-pending applications CREEP034, CREEP036, and CREEP037, filed concurrently herewith, which are incorporated herein by reference for all purposes.

### BACKGROUND OF THE INVENTION

This invention relates generally to semiconductor transistors, and more particularly the invention relates to laterally diffused MOS (LDMOS) transistors.

The LDMOS transistor is used in RF/microwave power amplifiers. The device is typically fabricated in an epitaxial silicon layer (P−) on a more highly doped silicon substrate (P+). A grounded source configuration is achieved by a deep P+ sinker diffusion from the source region to the P+ substrate, which is grounded. (See, for example, U.S. Pat. No. 5,869,875.)

The gate to drain feedback capacitor (CGD) of any MOSFET device must be minimized in order to maximize RF gain and minimize signal distortion. The gate to drain feedback capacitance is critical since it is effectively multiplied by the voltage gain of the device.

Heretofore, the use of a Faraday shield made of metal or polysilicon formed over the gate structure has been proposed as disclosed in U.S. Pat. No. 5,252,848. (See, also U.S. Pat. No. 6,215,152 for MOSFET HAVING SELF-ALIGNED GATE AND BURIED SHIELD AND METHOD OF MAKING SAME.)

It would be advantageous to connect the gate shield to RF ground to further reduce RF signal feedback from the drain to the gate and source.

### SUMMARY OF THE INVENTION

The present invention provides a source capacitor and gate shield structure which can be connected to permit RF grounding of the gate shield. Further, the shield can be DC voltage biased to reduce drain resistance without increased dopant concentration within in the lightly doped drain extension from the drain to the channel.

In a preferred embodiment, a stacked metal structure is provided which readily accommodates gold plating for the shield and source capacitor integral structure.

The invention and objects and features thereof will be more readily apparent from the following detailed description and appended claims when taken with the drawings.

### BRIEF DESCRIPTION OF THE DRAWINGS

FIGS. 1A, 1B are perspective views of two embodiments of LDMOS transistors in accordance with the invention.

FIGS. 2-19 are section views illustrating steps in fabricating the LDMOS transistor of FIG. 1.

FIGS. 20-24 are section views illustrating the fabrication of capacitor structures on field oxide in accordance with another embodiment of the invention.

### DETAILED DESCRIPTION OF ILLUSTRATIVE EMBODIMENTS

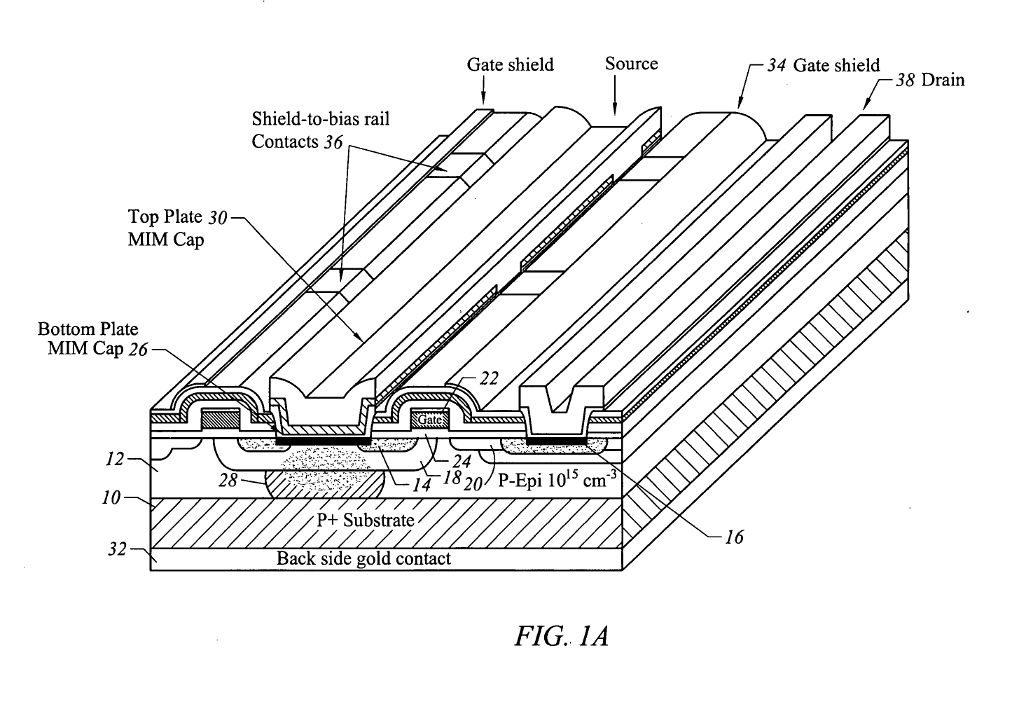

FIGS. 1A and 1B are perspective views of two embodiments of LDMOS transistors with integral gate shield and source capacitor plate in accordance with the invention. The two embodiments are very similar and like elements have the same reference numerals. In FIG. 1A, the transistor is fabricated on a P+ semiconductor substrate 10 which includes a P− epitaxial silicon layer 12. The surface of epitaxial layer 12 includes N-doped source 14 and N-doped drain 16 with a P-doped channel 18 positioned there between. A lightly doped drain (LDD) extension 20 extends from drain 16 towards channel 18. Gate 22, typically doped polysilicon, is formed over channel 18 and separated therefrom by a gate insulator such as silicon oxide 24.

A metal layer 26 on the surface of epitaxial layer 12 contacts source 14 and a P+ sinker 28 which connects layer 26 to substrate 10 and a backside metal contact 32. An insulator such as silicon nitride separates bottom plate 26 from a top plate 30 of a source capacitor structure. Plate 30 is connected to and integral with a gate shield 34 above and spaced from gate 22 by suitable electrical insulation. Metal ribs 36 electrically and physically join shield 34 and capacitor plate 30. A drain contact 38 is made to drain 16 with shield 34 positioned between gate 22 and drain contact 38.

By providing a capacitive structure over source 14, the gate can be effectively RF grounded through the capacitor to a grounded backside contact 32. Moreover, a positive DC voltage bias can be applied to gate shield 34 which induces negative carriers in gate extension 20 thus increasing the conductivity of the drain extension without increased doping, which would adversely affect reverse breakdown voltage.

FIG. 1B is another embodiment of an LDMOS transistor in accordance with the invention which is similar to the transistor of FIG. 1A. However, in this embodiment the source capacitance is increased by providing an undulating bottom metal plate 26 which is interdigitated with corresponding undulations or fingers of source contact 30. The undulations increase the total surface area of the capacitor plates thereby increasing the capacitance within the same footprint on the semiconductor surface.

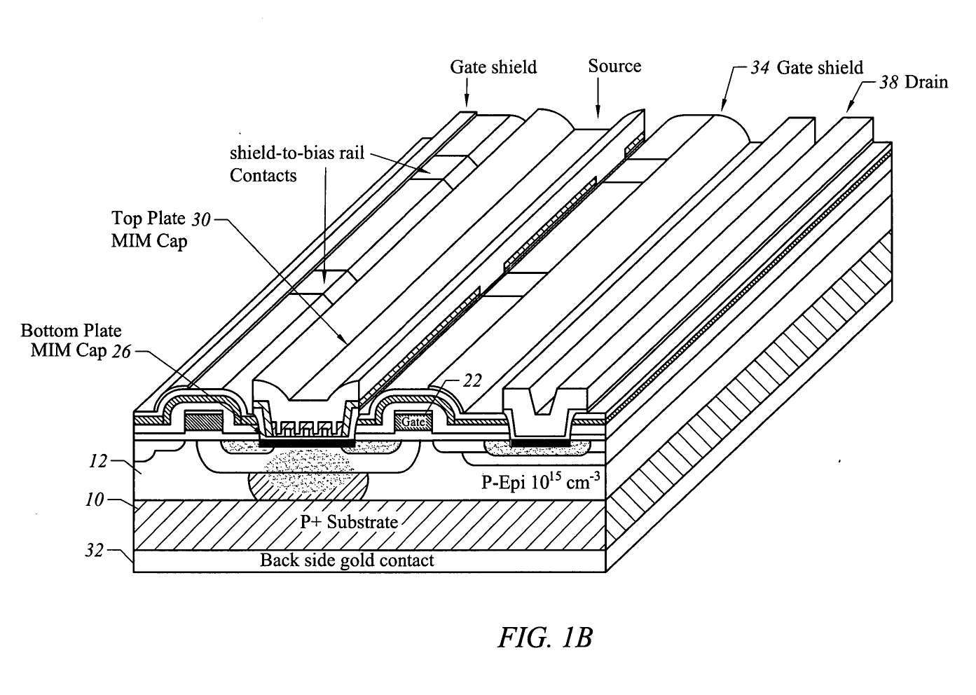

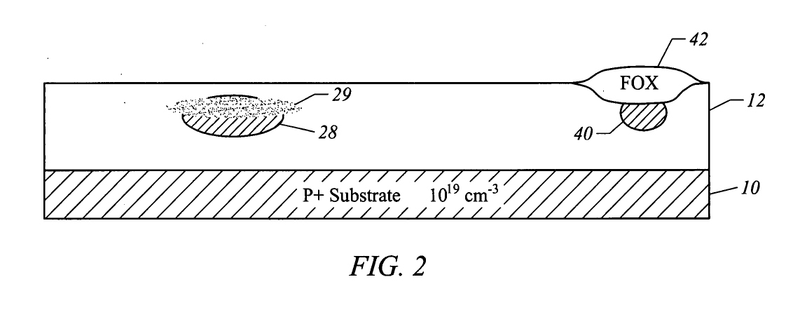

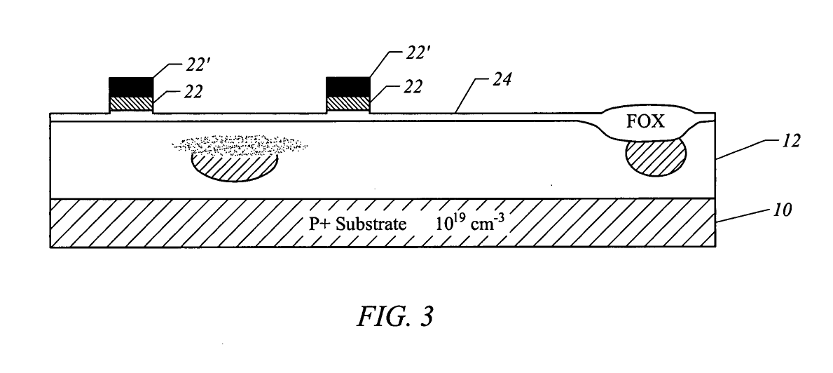

A LDMOS transistor in accordance with the invention is readily fabricated using conventional semiconductor processing techniques, as will be described with reference to the section views of FIGS. 2-19. In fabricating preferred embodiments of the transistors, a stacked conductive metal structure of titanium tungston (TiW), -titanium tungston nitride (TiWN), -titanium tungston (TiW), and gold (Au) is employed in forming the metal layers. The stacked structure with a coating of gold facilitates the later plating of a thicker layer of gold with the titanium tungston nitride blocking the migration of gold atoms through the structure. Processing in the illustrated embodiment begins with a P+ substrate 10 of 10¹⁹ cm⁻³ on which is formed a P− epitaxial silicon layer 12 of 10¹⁵ Cm³ atoms. As shown in FIG. 2, a P+ boron implant 28 followed by a shallower boron implant 29 are made for the subsequent formation of the P+ sinker 28 and surface contact. P+ implant 40 is made at the same time as implant 28 as a ground ring for terminating electric fields, and a field oxide 42 is then formed on the surface of epitaxial layer 12 but removed in the regions for the transistor structures. Thereafter, as shown in FIG. 3, gates 22 are formed for two adjacent transistors on a surface gate oxide 24 with a refractory metal silicide contact 22′ formed on the surface of each gate 22. Thereafter, as shown in FIG. 4 the surface of the epitaxial layer is covered with a photoresist mask with an opening provided for implanting a light dope of boron (6.65 E 13 at 35 KeV) between the gate structures for the subsequent lateral diffusion of the P dopants by annealing under the gate structures and forming the channel regions 18.

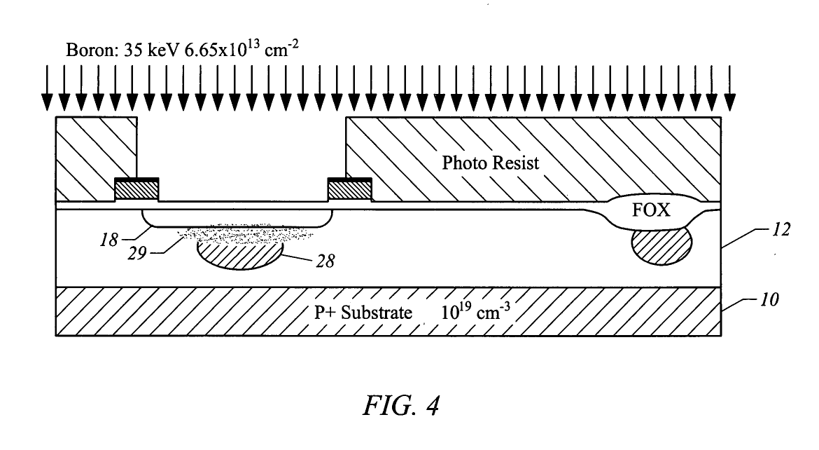

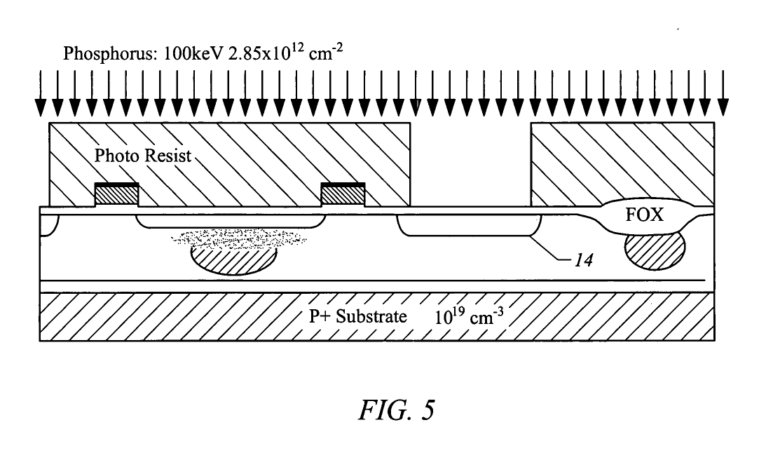

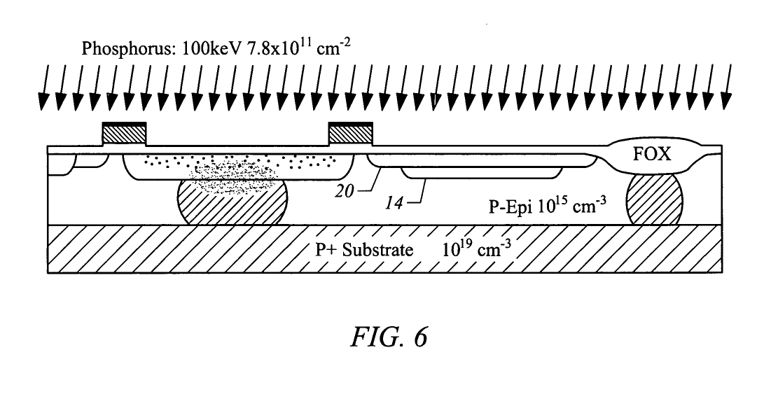

In FIG. 5 a second photoresist mask is provided with a window over the drain region through which a light N implant (phosphorous at 2.85 E 12 at 100 KeV) is made for the subsequent formation of the lightly doped drain extensions. Next, as shown in FIG. 6 a N-dopant implant (phosphorous 7.8 E 11 cm⁻² at 100 KeV) is made in the drain region and in the source region which is sufficient for subsequent formation of source regions 14 by annealing as shown in FIG. 7, as well as the drain extension 20. A thicker insulation layer comprising deposited silicon oxide 50, silicon nitride 51, and silicon oxide 52 is formed over a surface of the structure.

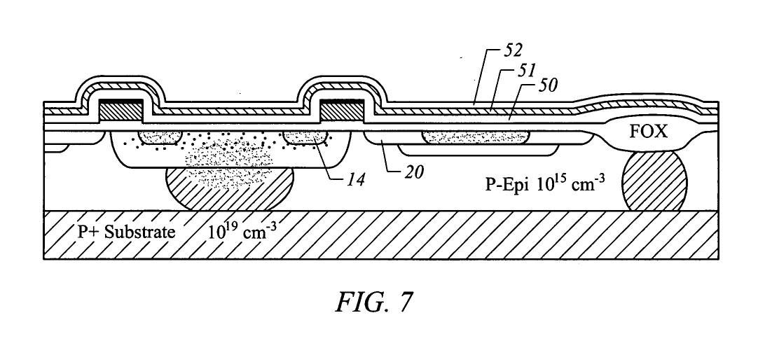

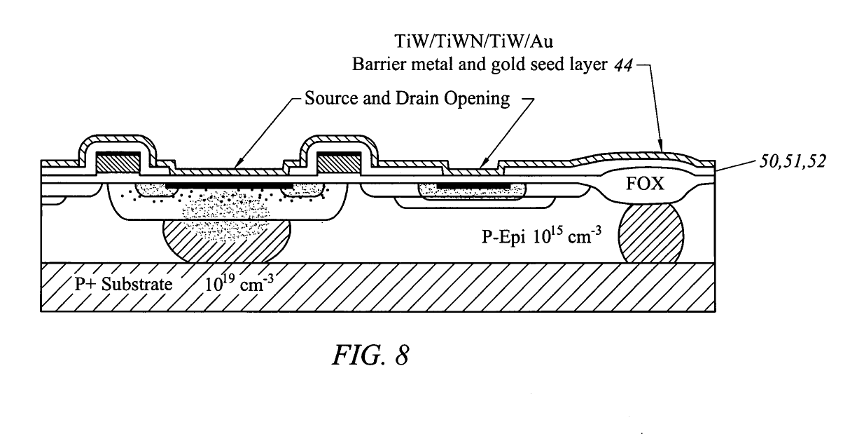

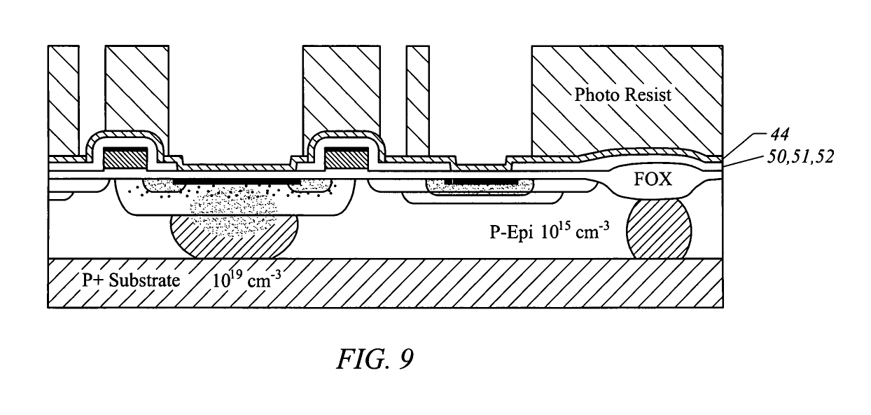

Having now completed the basic transistor structure, fabrication of the capacitor structure, gate shield, and metal layers will be described. In FIG. 8 openings are made to the source and drain regions, silicide contacts will be formed and then a metal layer stack 44 of TiW, TiWN, and TiW is applied over the surface of the structure with a thin coating of gold on the top TiW layer. Typical thickness is 2500 Å with 500 Å of gold. For simplicity in the drawing, oxide layer 50, nitride layer 51, and oxide layer 52 are now shown as one layer under metal layer stack 44. Next, as shown in FIG. 9, a photoresist mask is applied to the surface for the subsequent plating of gold on the source region, shield region, and drain, as shown in FIG. 10 with bottom capacitor plate 26 and metal plate 16′ to drain 16, and gate shield 34.

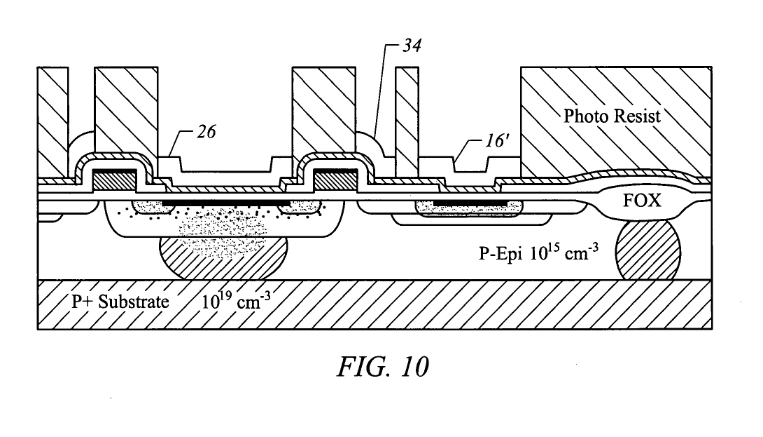

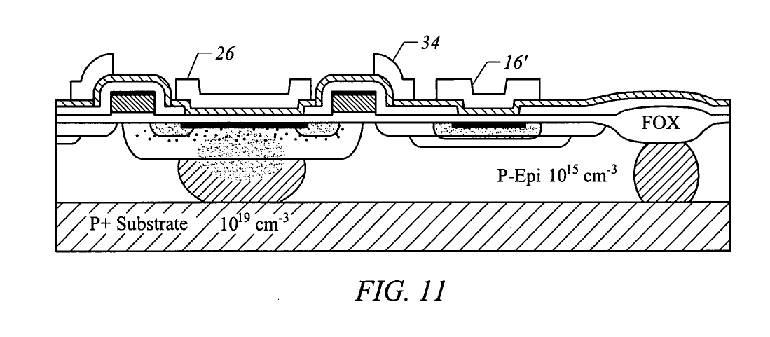

Thereafter, the photoresist is removed as shown in FIG. 11, and then the exposed thin gold seed layer from FIG. 8 is removed by etching along with the underlying TiW stack layers as shown in FIG. 12. Contacts 26, 34, and 38 are now electrically isolated from one another.

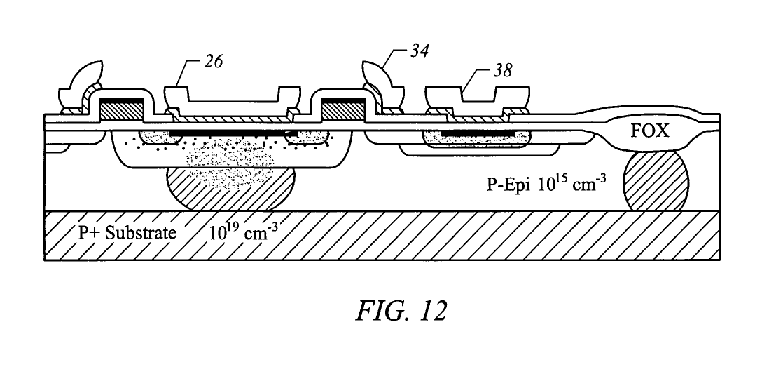

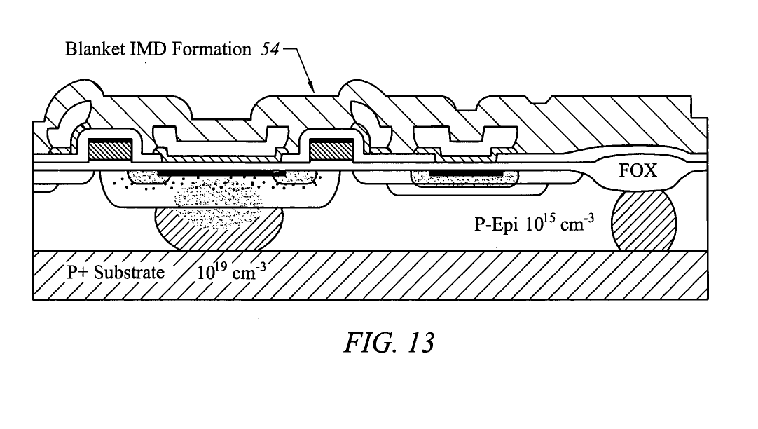

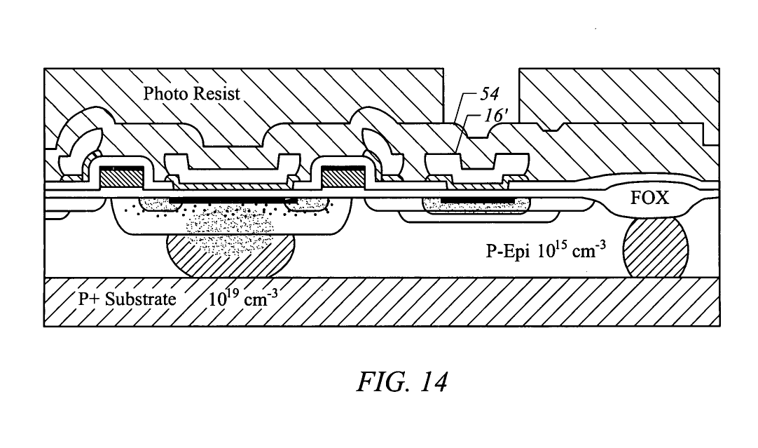

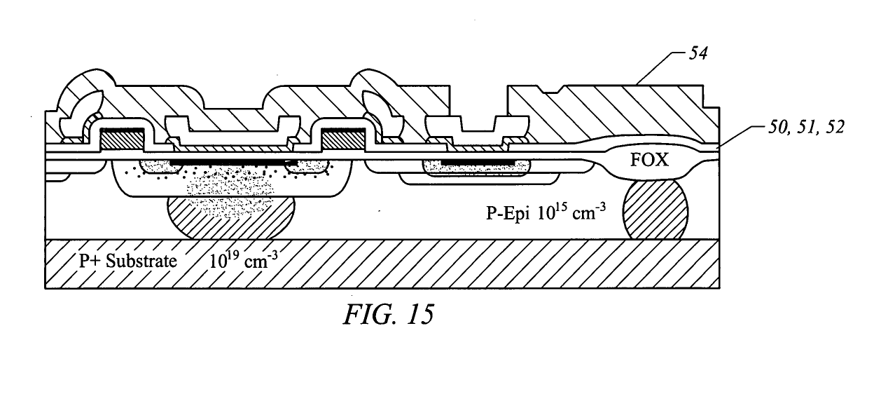

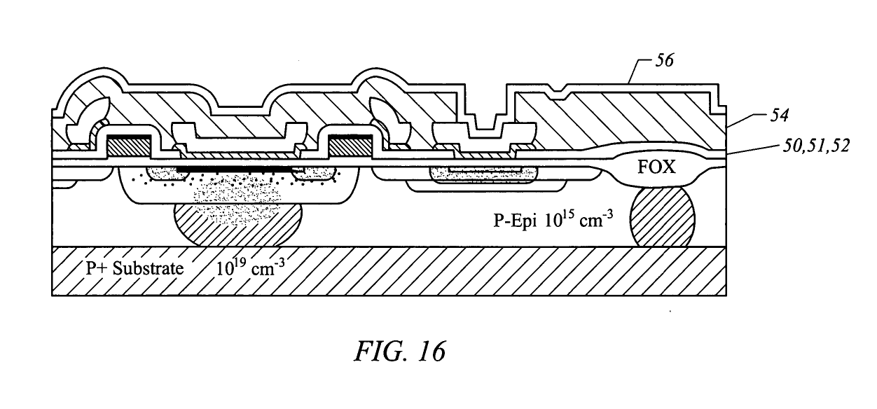

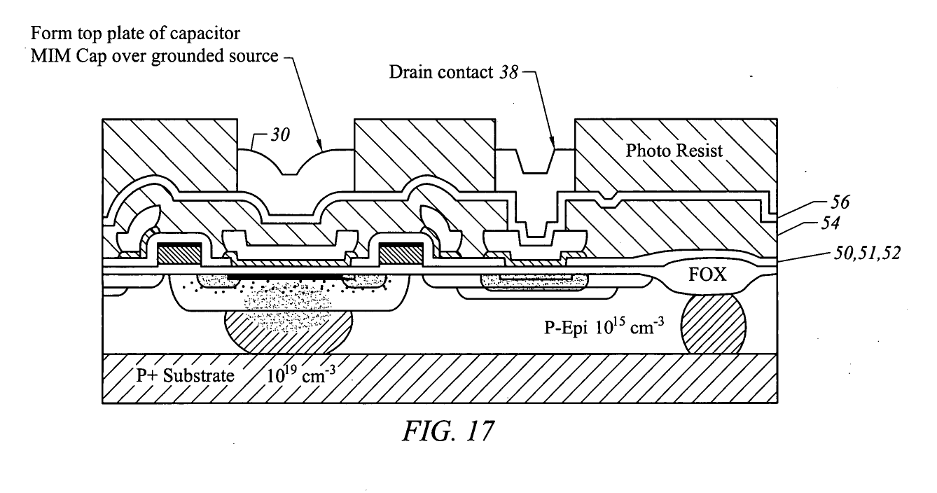

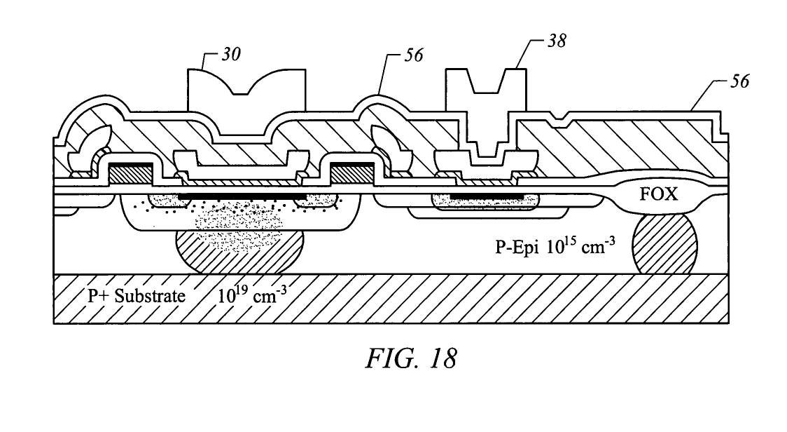

In FIG. 13, silicon nitride layer 54 is deposited and will become the source capacitor dielectric. The dielectric material can be changed in accordance with the desired capacitance since a high K dielectric (e.g., oxide, nitride, Al₂O₃, TaO₅) increases capacitance whereas a low K dielectric (e.g., BPSG, TEOS) will minimize capacitance. In FIG. 14 a photoresist mask is applied with an opening over drain contact 16′ for removal of dielectric 54 as shown in FIG. 15. The underlying gold layer acts as an etch stop. In this same process step, the gate and shield contact areas are also exposed for removal of dielectric 54 (not shown). Following the removal of dielectric 54, a metal layer 56 (TiW, TiWN, TiW, gold) is formed over the surface as shown in FIG. 16. A photoresist mask is applied as shown in FIG. 17 and then gold is plated for source contact 30 and drain contact 38. The photoresist mask is then stripped as shown in FIG. 18 and then the exposed metal layer 56 is removed by etching, similar to the process in FIG. 12. At this point and as shown in FIG. 19, the device is essentially complete except for backside contact metallization and any overlying metallization interconnecting various devices.

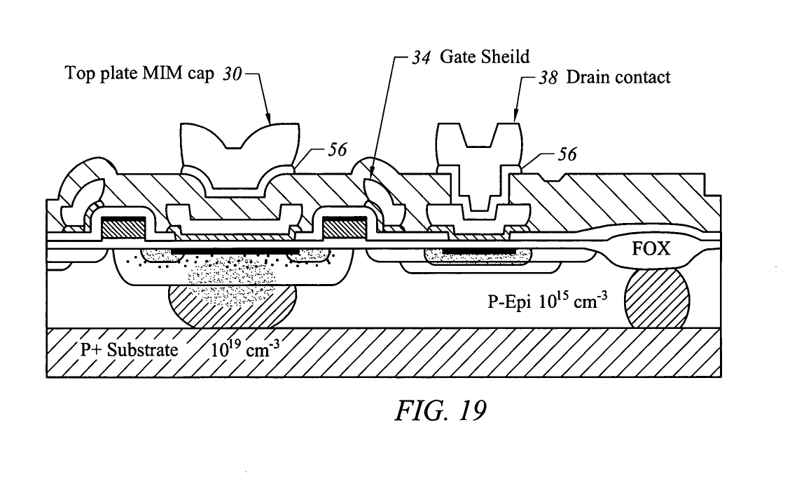

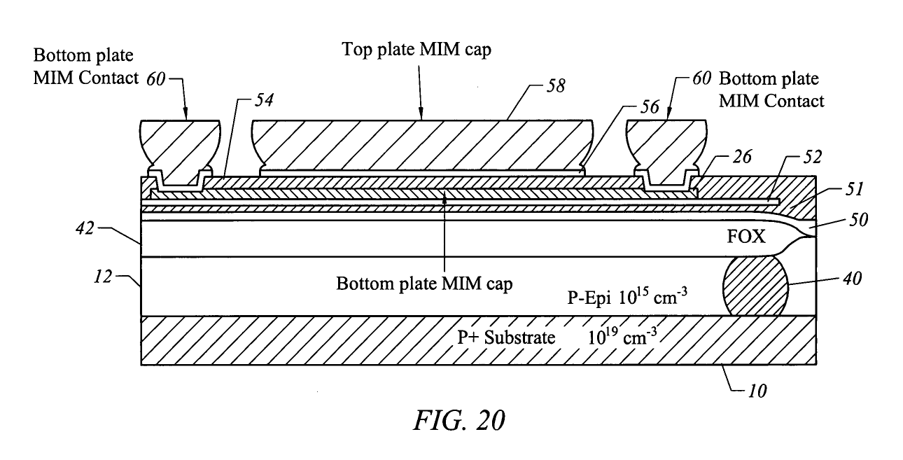

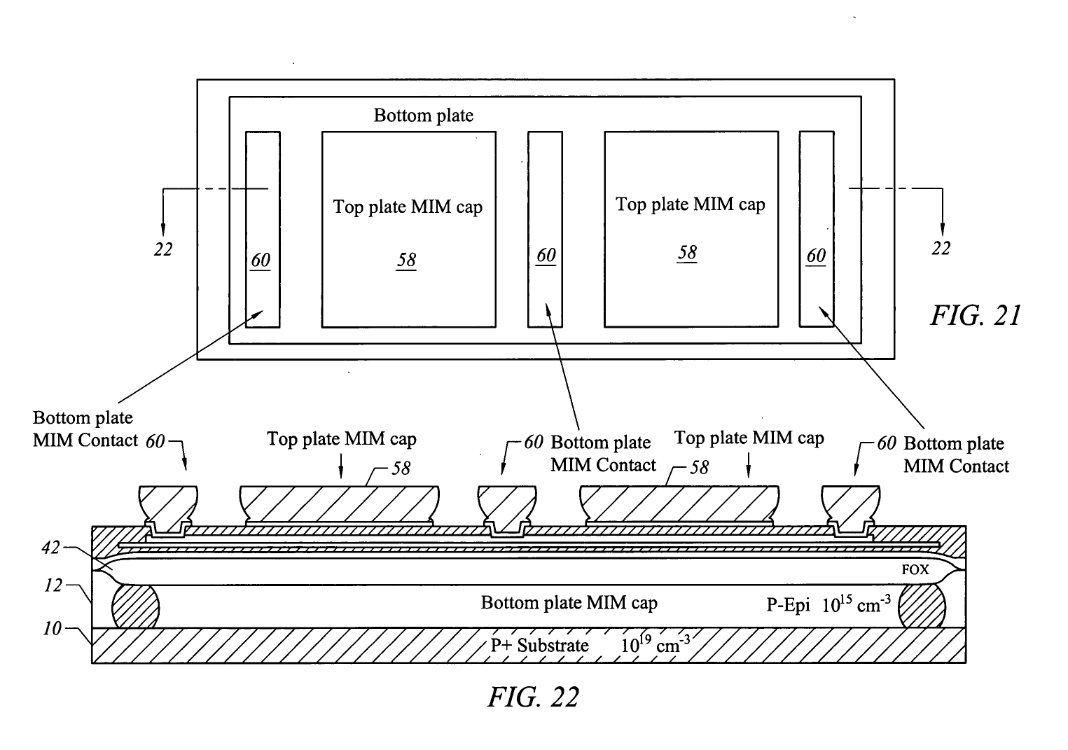

In accordance with another embodiment of the invention, capacitor structures can be formed over the field oxide away from the active transistor devices during the transistor processing. In FIG. 20, the composite dielectric of silicon oxide 50, silicon nitride 51 and silicon oxide 52, extends over field oxide 42. The bottom plate 26 of the source capacitor overlies this composite insulating layer, and capacitor dielectric 54 separates bottom plate 26 from the stacked metal layer 56 and overlying gold metallization 58. Contacts 60 to bottom metal layer 26 are made through dielectric 54. FIG. 21 is a plan view illustrating a layout of a field oxide capacitor structure and FIG. 22 is a section view along section line 22 in FIG. 21.

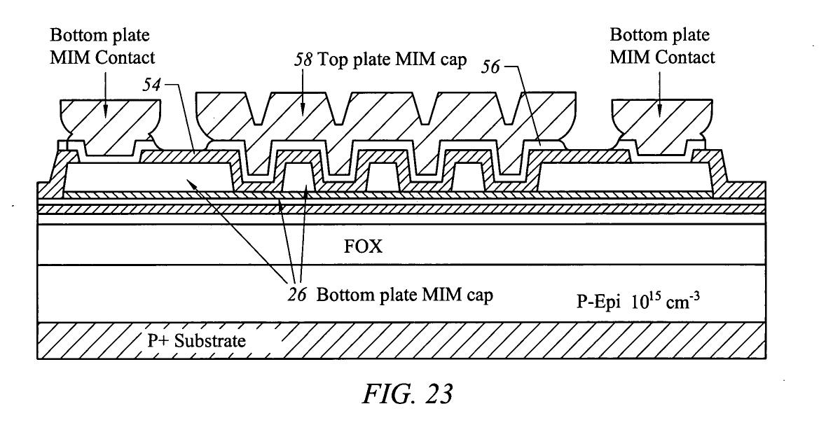

Similar to the source capacitor structure in FIG. 1B, the capacitance over the field oxide can be increased by using an undulating structure in which the bottom metal plate 26 is selectively patterned to form undulations which are interdigitated with undulations in top plate 58 as shown in FIG. 23.

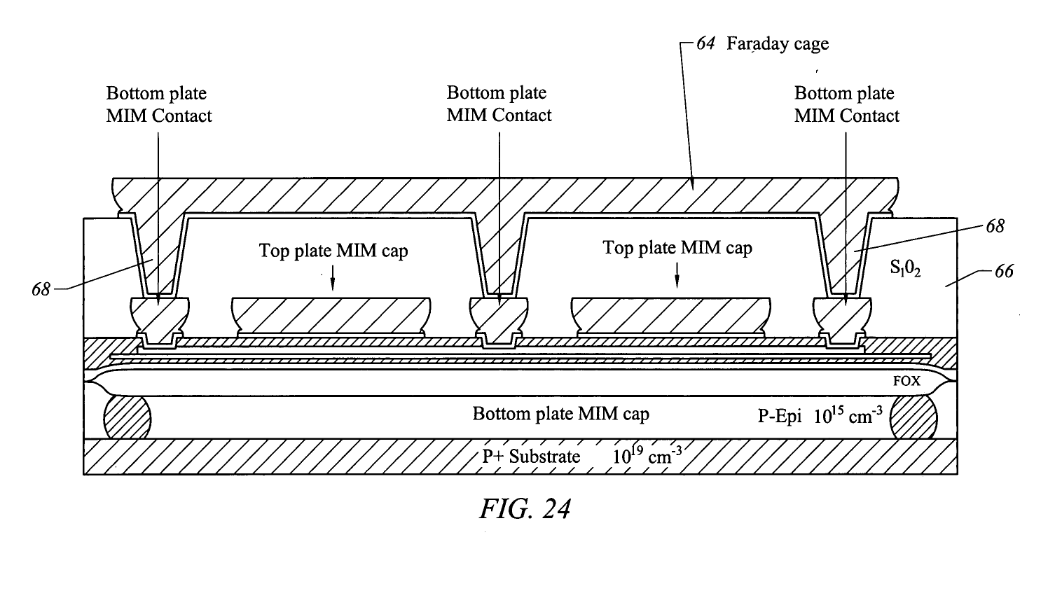

FIG. 24 is a section view illustrating the use of a Faraday cage 64 over and shielding the field oxide capacitors. Here a thick layer of dielectric material such as silicon oxide or undoped polysilicon is applied over the capacitor structure with vias 68 connecting the top surface of the Faraday cage to the bottom plate of the field oxide capacitors.

There has been described a LDMOS transistor structure having a source capacitor interconnected with a gate shield and with the provision of capacitors over field oxide to increase capacitance value. The structure permits the RF grounding of a gate shield while permitting the application of a DC positive voltage bias on the shield.

While the invention has been described with reference to specific embodiments, the description is illustrative of the invention and is not to be construed as limiting the invention. For example, while gold plating is described in the embodiments, other plating techniques can be used including copper and silver plating as well as others. Further, the capacitor structure can comprise a silicide bottom plate without plating. The top plate can comprise an aluminum layer. Thus, various modifications and applications may occur to those skilled in the art without departing from the true spirit and scope of the invention as defined by the appended claims.

1. A LDMOS transistor comprising:
a) a semiconductor substrate having a first major surface,
b) a source region and a drain region formed in the first major surface and spaced apart by a channel region,
c) a gate positioned over the channel region and separated therefrom by a gate dielectric layer,
d) a gate shield overlying a portion of the gate and separated therefrom by a shield dielectric layer, and
e) a source capacitor including the source region as part of one capacitor plate, a capacitor dielectric layer, and a second capacitor plate on the dielectric layer.

2. The LDMOS transistor as defined by claim 1 and further including:
f) a conductor interconnecting the second capacitor plate and the gate shield.

3. The LDMOS transistor as defined by claim 1 wherein the substrate includes a P+ substrate and a P− epitaxial layer on the substrate, the first major surface being a surface of the P− epitaxial layer.

4. The LDMOS transistor as defined by claim 3 and further including a P-doped sinker region extending through the epitaxial layer to the P+ substrate, the one capacitor plate including a conductive layer connected to the source region and through the P-doped sinker region to the substrate.

5. The LDMOS transistor as defined by claim 4 and further including a metal layer on a second major surface of the substrate opposite from the first major surface, the one capacitor plate being ohmically connected to the second major surface through the P-doped sinker.

6. The LDMOS transistor as defined by claim 5 wherein the conductor layer of the one capacitor plate comprises a stacked layer of TiW, TiWN, TiW, and Au.

7. The LDMOS transistor as defined by claim 5, wherein the gate shield comprises the stacked layer of TiW, TiWN, TiW, and Au.

8. The LDMOS transistor as defined by claim 7 wherein the second capacitor plate comprises a stacked layer of TiW, TiWN, TiW, and Au.

9. The LDMOS transistor as defined by claim 7 wherein the metal layer on the second major surface is DC grounded.

10. The LDMOS transistor as defined by claim 1 wherein the one capacitor plate is DC grounded.

11. The LDMOS transistor as defined by claim 1 and further including an adjacent capacitor over field oxide including a bottom plate over the field oxide, an insulator over the bottom plate, and a top plate on the insulator.

12. The LDMOS transistor as defined by claim 11 wherein the top plate comprises a stacked layer of TiW, TiWN, TiW, and Au.

13. The LDMOS transistor as defined by claim 12 and further including a Faraday cage over the adjacent capacitor to provide RF shielding.

14. The LDMOS transistor as defined by claim 13 wherein the top plate and the bottom plate of the adjacent capacitor have interdigitated surfaces to increase capacitor surface area.

15. The LDMOS transistor as defined by claim 14 wherein the first and second plates of the source capacitor have interdigitated surfaces to increase capacitor surface area.

16. The LDMOS transistor as defined by claim 1 wherein the first and second plates of the source capacitors have interdigitated surfaces to increase capacitor surface area.

17. A method of reducing drain to gate and drain to source capacitive feedback in a LDMOS transistor having source and drain regions separated by a channel controlled by an overlying gate, the method comprising the steps of:
a) providing a shield plate over the gate and adjacent to the drain,
b) providing a capacitive contact to the source region,
c) electrically connecting the capacitive contact and the shield plate, and
d) connecting the source to ground.

18. The method as defined by claim 17 and further including the step of:
e) applying a DC voltage to the shield plate to thereby increase conductance in an underlying drain region.
